(19) United States
(12) Patent Application Publication
(10) Pub. No.: US 2026/0048982 A1
(43) Pub. Date: Feb. 19, 2026

(54) METHOD FOR ATTACHING A BRIDGING METAL LAYER IN VIA HOLES FOR SUPPORTING POSTS

(71) Applicant: National Chung Shan institute of Science and Technology, Taoyuan (TW)

(72) Inventors: Shiang-Feng Tang, Taoyuan (TW); Hsin-Chang Chen, Taoyuan (TW); Hong-Yuan Zeng, Taoyuan (TW); Bing-Fang Tsai, Taoyuan (TW)

(21) Appl. No.: 18/801,758

(22) Filed: Aug. 13, 2024

(51) Int. Cl. B81C 1/00; B81B 7/02

(52) U.S. Cl. CPC B81C 1/00103; B81B 7/02; B81B 2201/0207; B81B 2203/0353; B81C 2201/0132; B81C 2201/0159; B81C 2201/0176

(57) ABSTRACT

A method for attaching a bridging metal layer in supporting post via holes in an integrated circuit device is provided. The method include: (A) providing an integrated circuit wafer with a first coating layer as the outermost layer; (B) forming a sacrificial layer on the first coating layer and then forming a dielectric supporting layer on the sacrificial layer to obtain multiple supporting post via holes; (C) forming a bridging metal layer in the supporting post via holes and then forming a second coating layer; and (D) forming a connecting metal layer on the bridging metal layer and then forming a third coating layer on the bridging metal layer to obtain multiple supporting posts.

### BACKGROUND

### Technical Field

The disclosure relates to a semiconductor process method. More particularly, the disclosure relates to a method for attaching a bridging metal layer in supporting post via holes.

### Description of Related Art

A microbolometer is a type of miniature thermal detector used to detect infrared radiation (IR) and convert IR into electrical signals. The microbolometer does not require a cooling system, and device complexity and power consumption are thus reduced. This makes the microbolometer more compact, robust, and suitable for portable applications. Microbolometers can detect a wide range of infrared radiation, including mid-infrared and far-infrared wavelengths, allowing them to detect small temperature changes over a larger temperature range.

Microbolometers are typically manufactured using Micro-Electro-Mechanical Systems (MEMS) technology and includes MEMS components, an infrared absorption layer, and a thermal sensing element. The infrared absorption layer converts infrared radiation from the environment into heat, while the MEMS components (e.g., micrometer-scale cantilever beams and supporting posts) expand slightly when receiving infrared radiation, converting this small change into a varying electrical signal. This signal can be processed and amplified to form a thermal image.

The microbolometer can be a thin-film micro-resistance sensor developed using MEMS process technology. The MEMS process includes a stacked membrane film supported by multiple posts, with each post containing a supporting post via hole. The base and periphery of the supporting post via holes have connecting metal films that guide the electrical signals from the sensor to the connecting metal area on the readout integrated circuit (ROIC). This setup ensures that the detected current or voltage signals are smoothly conducted through the connecting metal in the supporting post via holes, allowing for subsequent signal processing within the integrated circuit.

However, to achieve optimal infrared absorption, the height of the supporting posts in the stacked membrane film must generally exceed 2.5 μm. Additionally, the dry etching process used for forming the supporting post via holes in the posts and signal connections often results in anisotropic etching effects. This causes the supporting post via holes in the supporting posts to have a tapered shape, wider at the top and narrower at the bottom, with steep edges. Therefore, in prior art processes, it was necessary to control the angle of the steep cuts in the supporting post via holes of the supporting posts to ensure it did not exceed a specific angle. Precise control of the cut angle was essential; otherwise, the deposition of connecting metals could result in steep edge effects at the hole margins, leading to poor metal connections or even circuit breaks. This issue reduces process yield and affects the uniformity and imaging quality of array-type thin-film micro-resistance sensors.

As mentioned above, in current semiconductor processes, when the supporting post via holes for signal connections are too deep, poor control of process parameters can result in the deposition of connecting metals being too thin, leading to circuit breaks. Although other methods can achieve good process control, they often increase process time or cost.

### SUMMARY

Therefore, there is a pressing need in the industry to develop a process method for attaching bridging metal at the edges, constructing a process framework that balances cost and performance. The formation of a bridging metal layer prevents poor metal connections and circuit breaks, thereby improving process yield and achieving high-quality integrated circuit devices.

To improve upon the shortcomings of prior techniques, an aspect of the present invention provides a method for attaching a bridging metal layer within the supporting post via holes. This method integrates an integrated circuit wafer, a coating layer, a sacrificial layer, and multiple supporting posts to effectively enhance the yield of semiconductor processes.

The method for attaching a bridging metal layer in supporting post via holes for an integrated circuit device comprising the following steps: (A) providing an integrated circuit wafer with an outermost layer as a first coating layer; (B) forming a sacrificial layer on the first coating layer, and then forming a dielectric supporting layer on the sacrificial layer to obtain a plurality of supporting post via holes; (C) forming a bridging metal layer in the supporting post via holes and then forming a second coating layer; and (D) forming a connecting metal layer on the bridging metal layer and then forming a third coating layer on the bridging metal layer to obtain a plurality of supporting posts.

According to an embodiment of this invention, the first coating layer, the second coating layer, and the third coating layer are made from silicon nitride but are not limited to this material. These coating layers not only serve to isolate the upper and lower layers but also provide a flattening effect.

According to an embodiment of this invention, the sacrificial layer is made from polyimide but are not limited to this material.

According to an embodiment of this invention, the bridging metal layer is made from titanium but are not limited to this material.

According to an embodiment of this invention, the deposition area of the bridging metal layer is controlled using a photomask design.

According to an embodiment of this invention, the connecting metal layer is made from vanadium but are not limited to this material.

According to an embodiment of this invention, one end of the supporting post comprises a supporting post base.

According to an embodiment of this invention, the supporting post base comprises the supporting post via hole.

According to an embodiment of this invention, the supporting post base is cylindrical, elliptical, or rectangular.

The above summary, along with the following detailed description and accompanying drawings, aims to further illustrate the methods, techniques, and effects employed to achieve the intended aspects of this invention. Other aspects and advantages of the invention will be explained in the subsequent descriptions and illustrations.

### BRIEF DESCRIPTION OF THE DRAWINGS

FIG. 1 is a schematic diagram of a photomask design for a thin-film micro-resistance sensor according to one embodiment of the present invention.

FIG. 2 is a schematic diagram of Step 1 in a manufacturing process for a thin-film micro-resistance sensor according to one embodiment of the present invention.

FIG. 3 is a schematic diagram of Step 2 in the manufacturing process for a thin-film micro-resistance sensor according to one embodiment of the present invention.

FIG. 4 is a schematic diagram of Step 3 in the manufacturing process for a thin-film micro-resistance sensor according to one embodiment of the present invention.

FIG. 5 is a schematic diagram of Step 4 in the manufacturing process for a thin-film micro-resistance sensor according to one embodiment of the present invention.

### DETAILED DESCRIPTION

The following specific examples illustrate the embodiments of the present invention. Those skilled in the art can easily understand other advantages and effects of the invention from the content disclosed in this description.

The application scope of the present invention mainly lies in semiconductor processes that require electrical connections between homogeneous or heterogeneous components and circuits using metal signal connection vias. The invention is exemplified using a thin-film micro-resistance sensor. The method ensures the connection quality of the underlying integrated circuit (such as ROIC stated above) board (or wafer) by utilizing a connecting metal in a signal connection vias (i.e., supporting post via holes) at one end of the columnar supporting posts. The main principle involves depositing a bridging metal layer within the supporting post via holes after the dry etching process used for forming the supporting post via holes and before sputtering the connecting metal on the columnar supporting posts of the thin-film micro-resistance sensor. If the deposition area of the bridging metal layer is circular, its diameter should be larger than the maximum diameter of the supporting post via hole within the supporting post base and not larger than the supporting post base itself.

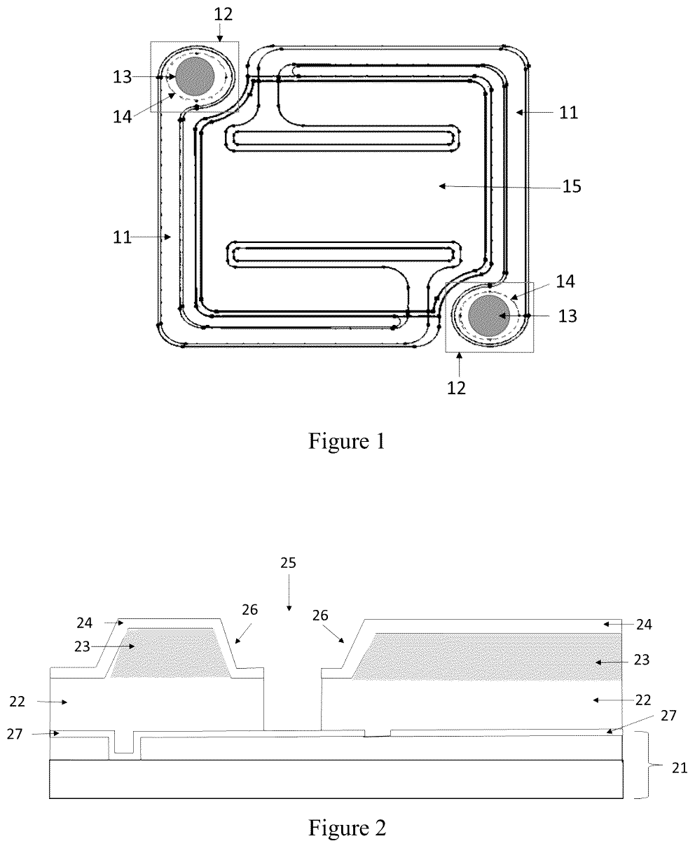

Please refer to FIG. 1, which is a top view showing seven stacked photomasks designed for a thin-film micro-resistance sensor according to one embodiment of the present invention. As shown in FIG. 1, the first to seventh photomasks defines the unit structure of a thin-film micro-resistance sensor are stacked from bottom to top. The thin-film micro-resistance sensor includes multiple supporting posts 11, multiple supporting post bases 12, supporting post via holes 13, a deposition area 14 of a bridging metal layer defined by the photomask design, and an infrared sensing area 15. In this embodiment, the deposition area 14 of the bridging metal layer is controlled using the photomask design. The deposition area 14 is designed to be larger than the supporting post via holes 13 within the supporting post bases 12 to cover the entire interior of the supporting post via holes 13 and not larger than the outer boundary of the supporting post bases 12.

Please refer to FIG. 2, which is a schematic diagram of Step 1 in a manufacturing process for a thin-film micro-resistance sensor according to one embodiment of the present invention. As shown in FIG. 2, after completing the fabrication of the integrated circuit wafer 21 at a wafer factory and conducting electrical function tests to meet design specifications, the integrated circuit wafer 21 is then moved into a cleanroom for optical microscope (OM) inspection. This OM inspection checks for surface flatness, cleanliness, and etc. Typically, a flatness compensation process is performed, and a first coating layer 22, such as made from silicon nitride in this embodiment, is grown on the surface of the integrated circuit wafer 21. The surface of the integrated circuit wafer 21 is then cleaned using physical or chemical cleaning processes.

Next, a sacrificial layer 23, such as made from polyimide (PI), is applied, followed by processes such as temperature curing and moisture removal. The thickness of the polyimide (PI) sacrificial layer 23 is determined based on one-fourth the wavelength of the energy absorption peak of the thin-film micro-resistance sensor, ensuring efficient energy absorption through constructive interference similar to an optical resonance cavity. A first photomask is then used in development and etching processes to define the thin-film micro-resistance sensor's sacrificial layer 23 and the supporting post via holes 25. The supporting post via holes 25 act as signal connection vias later.

During the etching process of the supporting post via holes 25, it is critical to control the angle of the steep cuts 26 within the supporting post via holes 25. If the angle exceeds a specific threshold, the subsequent deposition of metals may result in steep edge effects within the supporting post via holes 25, leading to poor metal connections or circuit breaks, thus reducing process yield. Therefore, precise control of the cut angle within the supporting post via holes 25 is crucial. If the internal shape of the supporting post via holes 25 is too steep, the sputtered metal may be too thin and cause circuit breaks. If the internal shape of the supporting post via holes 25 is too shallow, it may cause excessive widening of the supporting post via holes 25, leading to short circuits between adjacent thin-film micro-resistance sensors during the subsequent sputtering process.

The dielectric supporting layer 24, such as made from silicon nitride in this embodiment, is then deposited by plasma-enhanced chemical vapor deposition (PECVD). A second photomask is then used to define the via hole shapes at the bottom of the supporting post via holes 25. An enhanced anisotropic dry etching process using an inductively coupled plasma reactive ion etching (ICP-RIE) system is performed to improve etching efficiency and precision.

The etching temperature, gas flow rate, and power of the ICP-RIE system must be precisely controlled, while preventing side etching of the dielectric supporting layer 24 within the supporting post via holes 25 to avoid exposing the polyimide (PI) sacrificial layer 23. If the sidewalls of the supporting post via holes 25 expose the polyimide (PI) sacrificial layer 23, the organic stripper used to clean photoresist residues within the supporting post via holes 25 may erode the polyimide (PI), leading to insufficient support and collapse of the thin-film micro-resistance sensor after subsequent polyimide (PI) removal processes.

Additionally, precise control of the etching power and time of the ICP-RIE system is necessary to avoid over-etching, which can cause re-sputtering of the aluminum/nickel alloy (Al/Ni) electrode layer 27 on the integrated circuit wafer 21. Re-sputtered metals mixed with chlorine-based etching gases used in the ICP-RIE system can form aluminum chloride salts that accumulate at the bottom of the supporting post via holes 25, significantly increasing contact resistance and impacting signal connection quality and sensor noise.

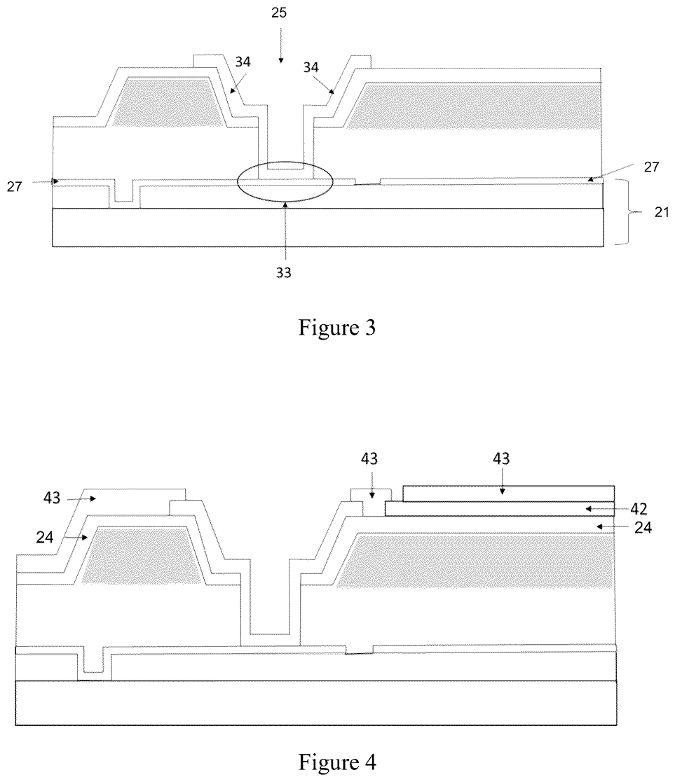

Please refer to FIG. 3, which is a schematic diagram of Step 2 in the manufacturing process for a thin-film micro-resistance sensor according to one embodiment of the present invention. As shown in FIG. 3, the invention provides a bridging metal layer 34, which is made from titanium (Ti) in this embodiment. In this step, the bridging metal layer 34 is deposited using a photomask design to control its deposition coverage area. The deposition area is designed to be larger than the supporting post via holes 25 within the supporting post bases to cover the entire interior of the supporting post via holes 25, but not exceeding the boundaries of the supporting post bases. This ensures that the subsequent sputtering of the connecting metal layer on the supporting post bases can be securely and tightly connected to the signal connection area 33 on the underlying integrated circuit wafer 21 through the bridging metal layer 34. This ensures that when the thin-film micro-resistance sensor operates normally and absorbs target thermal energy signals, the converted electronic signals can be stably conducted from the connecting metal on the supporting post base, through the bridging metal layer 34 deposited within the via holes 25, to the aluminum/nickel alloy (Al/Ni) electrode layer 27 on the top layer of the integrated circuit wafer 21. As described, in this embodiment, a bridging metal layer 34 of titanium (Ti) with a thickness of 100-300 nm is sputtered onto the supporting post via holes 25 and the outer edges of the supporting post base. This design ensures that even if the bottom edge of the supporting post via holes 25 is nearly vertical, the titanium layer can still be completely deposited in contact with the aluminum/nickel alloy (Al/Ni) electrode layer 27 without causing circuit breaks to significantly improve process tolerance and yield.

Please refer to FIG. 4, which is a schematic diagram of Step 3 in the manufacturing process for a thin-film micro-resistance sensor according to one embodiment of the present invention. As shown in FIG. 4, on the already prepared dielectric supporting layer 24, an infrared sensing layer 42 is deposited using a DC magnetron sputtering system. The infrared sensing layer 42 is generally a negative temperature coefficient polycrystalline composite metal oxide, and it is vanadium oxide in this embodiment. The infrared sensing layer 42 acts as the main absorption layer of the sensor, capable of adjusting its resistance according to the amount of absorbed thermal signals, thereby detecting external energy and quantitatively measuring the temperature or temperature changes of external objects. The infrared sensing layer 42 is defined by a fourth photomask to set its size and position. Then, a reactive ion etching (RIE) system or an inductively coupled plasma reactive ion etching (ICP-RIE) system may be used to perform dry etching to complete the step of patterning the infrared sensing layer 42.

Next, a second coating layer 43, such as made from silicon nitride in this embodiment, is deposited on the infrared sensing layer 42 by plasma-enhanced chemical vapor deposition (PECVD). A fifth photomask is used to define the pattern of the second coating layer 43, and a dry etching process is employed to partially remove the second coating layer 43.

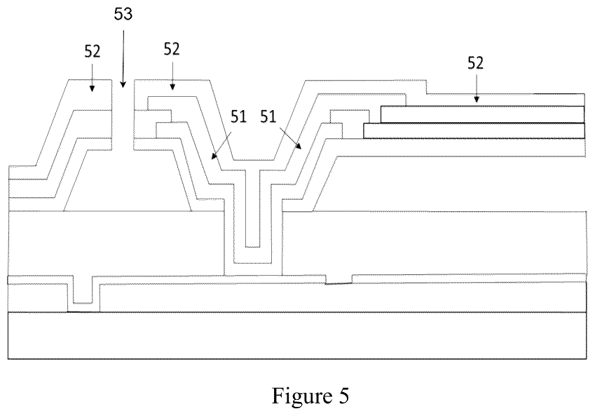

Please refer to FIG. 5, which is a schematic diagram of Step 4 in the manufacturing process for a thin-film micro-resistance sensor according to one embodiment of the present invention. As shown in FIG. 5, a connecting metal layer 51, such as made from vanadium in this embodiment, is deposited using a DC magnetron sputtering system. A sixth photomask is used to define the area of the connecting metal layer 51. The connecting metal layer 51 extends from the infrared sensing area, crossing over the L-shaped (but not limited to this shape) supporting posts to the bridging metal layer 34 within the supporting post via holes 25. Although the depth-to-width ratio of the supporting post via holes 25 is relatively large, and the supporting posts need to consider low thermal conductivity design to support the floating thin film layer of the infrared sensing area, the connecting metal layer 51 (vanadium) is designed to be as thin and narrow as possible (in this embodiment, 30 nm thick and 0.5 μm wide). This connecting metal layer 51 is still able to be stably and almost unaffected by the cut angle of the supporting post via holes 25 to be completely deposited on the bridging metal layer 34 (titanium layer thickness 100-300 nm). This ensures smooth signal conduction to the circuits on the integrated circuit wafer, significantly improving contact yield (low break rate), reducing contact resistance (lowering 1/f low-frequency noise of the thin-film micro-resistance sensor), without affecting the thermal insulation effect of the infrared sensing area after absorbing target heat, and maintaining the intrinsic thermal response value of the infrared sensing area.

Finally, a third coating layer 52, such as made from silicon nitride in this embodiment, is deposited. A seventh photomask is used to define the pattern of the third coating layer 52. After RIE etching, oxygen plasma ashing is used to remove the polyimide (PI) sacrificial layer 23 through the etched non-silicon nitride areas (such as opening 53), thereby completely constructing the supporting posts and finalizing the floating thin-film micro-resistance sensor manufacturing process.

The above embodiments are merely illustrative of the features and effects of the present invention and are not intended to limit the scope of the technical content of the invention. Any person skilled in the art can make modifications and variations to the above embodiments without departing from the spirit and scope of the invention. Therefore, the scope of protection of the present invention should be defined by the following claims.

What is claimed is:

1. A method for attaching a bridging metal layer in supporting post via holes for an integrated circuit device, the method comprising
(A) providing an integrated circuit wafer with an outermost layer as a first coating layer;
(B) forming a sacrificial layer on the first coating layer, and then forming a dielectric supporting layer on the sacrificial layer to obtain a plurality of supporting post via holes;
(C) forming a bridging metal layer in the supporting post via holes and then forming a second coating layer; and
(D) forming a connecting metal layer on the bridging metal layer and then forming a third coating layer on the bridging metal layer to obtain a plurality of supporting posts.

2. The method of claim 1, wherein the first coating layer, the second coating layer, and the third coating layer are made from silicon nitride.

3. The method of claim 1, wherein the sacrificial layer is made from polyimide.

4. The method of claim 1, wherein the bridging metal layer is made from titanium.

5. The method of claim 4, wherein the deposition area of the bridging metal layer is controlled using a photomask design.

6. The method of claim 1, wherein the connecting metal layer is made from vanadium.

7. The method of claim 1, wherein one end of the supporting post comprises a supporting post base.

8. The method of claim 7, wherein the supporting post base comprises the supporting post via hole.

9. The method of claim 7, wherein the supporting post base is cylindrical, elliptical, or rectangular.
